(19) United States
(12) Patent Application Publication
(10) Pub. No.: US 2025/0201557 A1
(43) Pub. Date: Jun. 19, 2025

(54) METHODS OF FORMING A BILAYER HARDMASK AND ASSOCIATED DEPOSITION METHODS USING A BILAYER HARDMASK

(71) Applicant: ASM IP Holding B.V., Almere (NL)

(72) Inventors: Devika Choudhury, Chandler, AZ (US); Kamesh Mullapudi, Tempe, AZ (US); Jereld Lee Winkler, Gilbert, AZ (US); Mihaela Balseanu, Scottsdale, AZ (US); Michael Schmotzer, Chandler, AZ (US)

(21) Appl. No.: 18/977,178

(22) Filed: Dec. 11, 2024

Related U.S. Application Data
(60) Provisional application No. 63/610,760, filed on Dec. 15, 2023.

(51) Int. Cl. H01L 21/033; C23C 16/02; C23C 16/40; C23C 16/455; H01L 21/02; H01L 21/311

(52) U.S. Cl. CPC H01L 21/0332; C23C 16/0227; C23C 16/403; C23C 16/45529; H01L 21/0206; H01L 21/02642; H01L 21/31111

(57) ABSTRACT

Methods for forming bilayer hardmasks are disclosed as well as methods for forming semiconductor structure using such bilayer hardmasks. The methods disclosed include performing a first cyclical deposition process to form a first hardmask layer and performing a second cyclical deposition process to form a second hardmask layer directly on the first hardmask layer. The methods also include forming CMOS structures using a bilayer hardmask.

### CROSS-REFERENCE TO RELATED APPLICATIONS

This application is a nonprovisional of, and claims priority to and the benefit of, U.S. Provisional Patent Application No. 63/610,760, filed Dec. 15, 2023 and entitled “METHODS OF FORMING A BILAYER HARDMASK AND ASSOCIATED DEPOSITION METHODS USING A BILAYER HARDMASK,” which is hereby incorporated by reference herein.

### FIELD

The present disclosure relates generally to the field of semiconductor processing methods, and associated structures and to the field of device and integrated circuit manufacture. More particularly the present disclosure generally relates methods for forming bilayer hardmasks and associated deposition methods using a bilayer hardmask. The present disclosure also generally relates to structures including a bilayer hardmask.

### BACKGROUND

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

For example, one challenge has been finding suitable hardmask materials utilized in the fabrication of the PMOS regions and the NMOS regions of CMOS device structures. Accordingly, novel hardmask materials and hardmask structures are desirable for improved CMOS fabrication methods.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

In accordance with examples of the disclosure methods of forming a bilayer hardmask on a substrate in a reaction chamber are provided. In such examples the method includes performing one or more deposition cycles of a first cyclical deposition process to deposit a first hardmask layer on the substrate, and performing one or more deposition cycles of a second cyclical deposition process to deposit a second hardmask layer directly on the metal oxide layer. The method may also include where a first unit deposition cycle of the first cyclical deposition process includes providing a first metal precursor to the reaction chamber and providing a first oxidizer to the reaction chamber. The method may also include where a second unit deposition cycle of the second cyclical deposition process includes providing a second metal precursor to the reaction chamber, providing a second oxidizer to the reaction chamber, and providing a second dopant precursor to the reaction chamber. The method may also include where the bilayer hardmask has an average layer thickness of less than 50 Angstroms. Other technical features may be readily apparent to one skilled in the art from the following figures, descriptions, and claims. The method may also include where the first hardmask layer includes an aluminum oxide. The method may also include where the first unit deposition cycle further includes providing a first dopant precursor to the reaction chamber. The method may also include where the first hardmask layer includes a first doped aluminum oxide. The method may also include where the second hardmask layer includes a second doped aluminum oxide. The method may also include where the second hardmask layer includes a hafnium doped aluminum oxide (HfAlO). The method may also include where the hafnium doped aluminum oxide has a hafnium concentration between 20 atomic-% and 60 atomic-%. The method may also include where the second hardmask layer includes a zirconium doped aluminum oxide (ZrAlO). The method may also include where the zirconium doped aluminum oxide has a zirconium concentration between 20 atomic-% and 60 atomic-%. Other technical features may be readily apparent to one skilled in the art from the following figures, descriptions, and claims.

In accordance with examples of the disclosure methods of forming a semiconductor structure are disclosed. In such examples the methods include seating a substrate, which includes a NMOS region and a PMOS region, into a reaction chamber, depositing a bilayer hardmask over the NMOS region and over the PMOS region, where depositing the bilayer hardmask includes, depositing a metal oxide layer over both the NMOS region and the PMOS region, and depositing a doped metal oxide layer directly on the metal oxide layer. The method also includes selectively removing the bilayer hardmask over the NMOS region to expose a surface of the NMOS region. The method also includes performing a cleaning process on the exposed surface of the NMOS region thereby forming a clean NMOS surface. The method also includes depositing a semiconductor layer on the clean NMOS surface. The method also includes removing a remaining portion of the bilayer hardmask disposed over the PMOS region. The method may also include selectively removing the bilayer hardmask over the NMOS region further includes, forming a patterned resist layer over the PMOS region and contacting an exposed region of the bilayer hardmask with a wet etchant selected from the group consisting of hydrofluoric acid, sulfuric acid, and phosphoric acid. The method may also include where the cleaning process removes the doped metal oxide layer over the PMOS region while maintaining at least the metal oxide layer over the PMOS region. The method may also include where the metal oxide layer comprise an aluminum oxide layer and the doped metal oxide layer includes a doped aluminum oxide layer. Other technical features may be readily apparent to one skilled in the art from the following figures, descriptions, and claims. The method may also include where depositing the semiconductor layer comprises a selective epitaxial deposition process. The method may also include where the selective epitaxial deposition process selectively deposits the semiconductor preferentially on the clean NMOS surface relative to a surface of the metal oxide layer. The method may also include where the surface of the metal oxide layer includes an amorphous surface. The method may also include where a dopant concentration in the doped aluminum oxide layer is between 20 atomic-% and 60 atomic-%. Other technical features may be readily apparent to one skilled in the art from the following figures, descriptions, and claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary method in accordance with one or more embodiments of the disclosure.

FIG. 2 illustrates an additional exemplary method in accordance with one or more embodiments of the disclosure.

FIG. 3 illustrates a semiconductor structure including substrate comprising a first region and a second region in accordance with one or more embodiments of the disclosure.

FIG. 4 illustrates a semiconductor structure including a first hardmask layer in accordance with one or more embodiments of the disclosure.

FIG. 5 illustrates a semiconductor structure including a second hardmask layer in accordance with one or more embodiments of the disclosure.

FIG. 6 illustrates a semiconductor structure including a patterned resist layer in accordance with one or more embodiments of the disclosure.

FIG. 7 illustrates a semiconductor structure after an etch process in accordance with one or more embodiments of the disclosure.

FIG. 8 illustrates a semiconductor structure after a cleaning process in accordance with one or more embodiments of the disclosure.

FIG. 9 illustrates a semiconductor structure including a semiconductor layer in accordance with one or more embodiments of the disclosure.

FIG. 10 illustrates a semiconductor structure after removing a first hardmask layer in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group Ill-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, a “structure” can be or include a substrate as described herein. Structures can include one or more layers overlying or within the substrate, such as one or more layers formed according to a method as described herein. Full devices or partial device portions can be included within or on structures.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

Various embodiments of the present disclosure relate to methods for forming a semiconductor structure and particularly semiconductor structures including a bilayer hardmask. Various embodiments of the present disclosure also relate to deposition methods employing a bilayer hardmask. In more detail, the processes employed in the fabrication of CMOS device structures can employ optimized hardmask materials to avoid the epitaxial deposition of semiconductor layers, such as, silicon germanium (SiGe) and phosphorus doped silicon (SiP), for example, in undesired locations.

In some CMOS fabrication methods, a metal oxide hardmask, such as, an aluminum oxide (AlOₓ) hardmask can be used during etch processes. However, a single layer metal oxide hardmask may include pinholes formed during the CMOS fabrication process and such pinholes may cause problems in downstream CMOS fabrication processes.

Various embodiments of the present disclosure include methods for forming and using a bilayer hardmask including a first hardmask layer and a second hardmask layer. For example, the first hardmask layer can comprise a metal oxide, such as, aluminum oxide, and the second hardmask layer can comprise a doped metal oxide, such as, a hafnium doped aluminum oxide or a zirconium doped aluminum oxide. In such examples, the second hardmask layer has a reduced dry etch rate relative to the first hardmask layer.

Therefore, the embodiments of the present disclosure employ a bilayer hardmask, such as, for example a metal oxide and a doped metal oxide rather than a single metal oxide hardmask layer, particular during fabrication processes requiring the masking of regions to prevent undesired epitaxial deposition in unwanted regions of the substrate thereby enable selective deposition methods. In some embodiments, the bilayer hardmask composed of a metal oxide and a doped metal oxide can be in form of a laminated structure. In some embodiments, the bilayer hardmask composed of a metal oxide and a doped metal oxide can be in form of a mixed doped metal oxide structure.

In accordance with examples of the disclosure, the upper hardmask layer (the second hardmask layer) can have a lower dry etch rate than the lower hardmask layer (the first hardmask layer). In such examples, the upper hardmask layer can be formed to a sufficiently low thickness that it can be removed by employing wet etch processes employed during the CMOS fabrication process. The CMOS fabrication processes of the present disclosure may employ a first wet etch step (e.g., employing dilute hydrofluoric acid), which can remove the bilayer hardmask from a first region (e.g., an NMOS region) of the substrate whilst maintaining the bilayer hardmask to protect a second region (e.g., a PMOS region) of the substrate.

In subsequent fabrication processes of the present disclosure step, the bilayer hardmask remaining over the second region of the substrate (e.g., the PMOS region) can be removed after epitaxial deposition of a semiconductor layer over the first region of the substrate (e.g., deposition over the NMOS region). The uppermost hardmask layer, having a lower etch rate, can be removed while still maintaining the underlying lower hardmask layer intact thereby avoiding the formation of any pin-holes in the lower hardmask layer. As a result, the subsequent epitaxial deposition processes on the NMOS region, for example, maintains protection for the PMOS region. In some embodiments, the employment of the bilayer hardmask and the methods of forming such a bilayer hardmask may be repeated again to protect the NMOS region during epitaxial deposit of a semiconductor layer (e.g., a SiGe semiconductor layer) over the PMOS region.

Therefore, the present disclosure may include methods for forming a semiconductor structure. In some embodiments, the methods can comprise, seating a substrate comprising a first region and a second region into a reaction chamber and forming a bilayer hardmask on the substrate. In some embodiments, forming the bilayer first hardmask layer can comprise, performing one or more deposition cycles of a first cyclical deposition process to deposit a first hardmask layer comprising a metal oxide on the substrate, and performing one or more deposition cycles of a second cyclical deposition process to deposit a second hardmask layer comprising a doped metal oxide layer directly on the first hardmask layer.

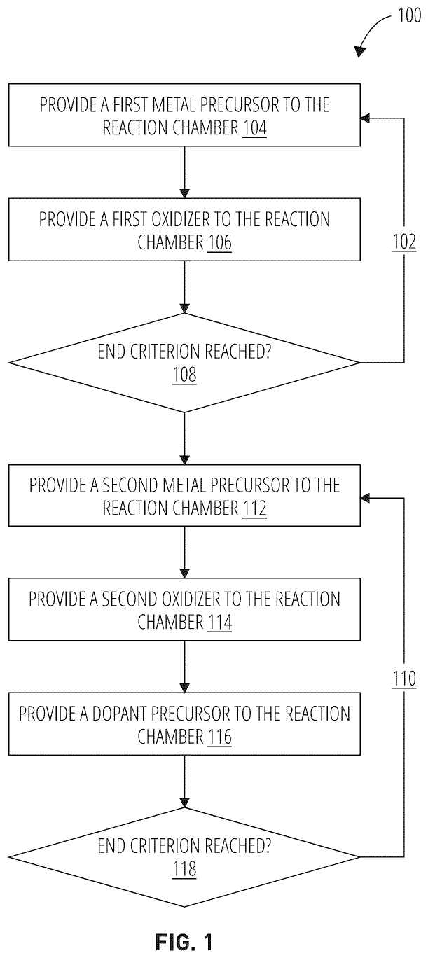

Turning now to the figures, FIG. 1 illustrates an exemplary method 100 that can be used to form a bilayer hardmask on a substrate comprising a first region and a second region. In brief, method 100 includes the steps of providing a substrate within a reaction chamber and performing a first cyclical deposition process 102 to deposit a first hardmask layer comprising a metal oxide layer and subsequently performing a second cyclical deposition process 110 to deposit a second hardmask layer comprising a doped metal oxide layer directly on the first hardmask layer, i.e., directly on the metal oxide layer. The first hardmask layer (i.e., the metal oxide layer) is disposed proximate to the substrate and the second hardmask layer (i.e., the doped metal oxide layer) is distal to the substrate and the combination of the first hardmask layer and the second hardmask layer makeup the bilayer hardmask.

In accordance with examples of the disclosure, method 100 includes the step of providing a substrate within a reaction chamber. In such examples, the reaction chamber employed for forming the bilayer hardmask is constructed and arranged for performing atomic layer deposition (ALD) processes. In other examples, the reaction chamber employed for forming the bilayer hardmask is constructed and arranged for performing cyclical chemical vapor deposition (CCVD) processes. In other examples, the reaction chamber employed for forming the bilayer hardmask is constructed and arranged for performing hybrid ALD/CCVD processes. In some embodiments, the reaction chamber is a standalone reaction chamber or part of a cluster tool. In some embodiments, the reaction chamber is be a batch processing tool. In some embodiments, a flow-type reactor can be utilized. In some embodiments, a showerhead-type reactor can be utilized. In some embodiments, a space divided reactor can be utilized. In some embodiments, a high-volume manufacturing-capable single wafer reactor may be utilized. In other embodiments, a batch reactor comprising multiple substrates can be utilized. For embodiments in which a batch reactor is used, the number of substrates may be in the range of 10 to 200, or 50 to 150, or even 100 to 130. The reactor can be configured as a thermal reactor—with no plasma excitation apparatus. Alternatively, the reactor can include direct and/or remote plasma apparatus.

In accordance with examples of the disclosure, the substrate disposed within the reaction chamber is heated to a desired deposition temperature for the deposition processes. In such examples, the substrate is heated to a substrate temperature of less than 800° C., less than 600° C., less than 400° C., or less than 200° C. In some embodiments of the disclosure, the substrate temperature may be greater than room temperature, between 200° C. and 800° C., or between 200° C. and 600° C., or between 200° C. and 400° C.

In addition to controlling the temperature of the substrate, the pressure in the reaction chamber may also be regulated to enable deposition of the bilayer hardmask. For example, in some embodiments of the disclosure, the pressure within the reaction chamber may be less than 760 Torr, or between 0.1 Torr and 10 Torr, or between 0.5 Torr and 5 Torr, or between 1 Torr to 4 Torr.

In accordance with examples of the disclosure, method 100 (FIG. 1) includes performing a first cyclical deposition process 102 to deposit a first hardmask layer comprising a metal oxide layer over a surface of a substrate and particular over a first region and over a second region of the substrate. For example, the embodiments of the present disclosure, may comprise, performing one or deposition cycles of a first cyclical deposition process 102 to deposit a metal oxide layer comprising an aluminum oxide over a surface of the substrate, and particularly over a surface of a first region and over a surface of a second region.

In some embodiments, the first cyclical deposition process 102 may comprise providing a first metal precursor to the reaction chamber (step 104) and providing a first oxidizer to the reaction chamber (step 106). The first metal precursor and the first oxidizer can be separately and/or sequentially provided to the reaction chamber, with or without intervening reaction chamber purge sequences. In some embodiments, step 104 and step 106 (and any intervening purge sequences) may constitute a first unit deposition cycle and the first unit deposition cycle can be repeated one or more times to deposit a first hardmask layer (e.g., the metal oxide layer) to a desired thickness on the substrate, and particularly over a first region and a second region of a substrate.

In accordance with examples of the disclosure, step 104 comprises providing a first metal precursor to the reaction chamber. The first metal precursor can be pulsed into the reaction chamber. The term “pulse” can be understood to comprise feeding a precursor into the reaction chamber for a predetermined amount of time. Unless otherwise noted, the term “pulse” does not restrict the length or duration of the pulse and a pulse may be any length of time. The first metal precursor pulse may be supplied to the reaction chamber along with a carrier gas flow. In some embodiments, the first metal precursor may comprise a volatile metal species that is reactive with the surface(s) of the substrate. The first metal precursor pulse may self-saturate the substrate surfaces such that excess constituents of the first metal precursor pulse do not further react with the molecular layer formed by this process.

The first metal precursor pulse is preferably supplied as a vapor phase reactant. The first metal precursor gas may be considered “volatile” for the purposes of the present disclosure if the species exhibits sufficient vapor pressure under the process conditions to transport species to the substrate surface in sufficient concentration to saturate the exposed surfaces.

In accordance with examples of the disclosure, the first hardmask layer can comprise an aluminum oxide layer and the step of providing the first metal precursor to the reaction chamber (step 104) can comprise providing an aluminum precursor to the reaction chamber. In such examples, the aluminum precursor is selected from the group consisting of trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), and triethyl aluminum (TEA). In some embodiments, the aluminum precursor is dimethylaluminum isopropoxide (DMAI).

In accordance with examples of the disclosure, method 100 includes providing a first oxidizer to the reaction chamber (step 106). In such examples, the first oxidizer is selected from the group consisting of water (H₂O), hydrogen peroxide (H₂O₂), ozone (O₃), oxides of nitrogen, such as, for example, nitrogen monoxide (NO), nitrous oxide (N₂O), and nitrogen dioxide (NO₂). In some embodiments, the first oxidizer comprises an organic alcohol, such as, isopropyl alcohol, for example.

In accordance with examples of the disclosure, the first cyclical deposition process 102 is repeated one or more time until a desired end criterion is reach (decision block 108). In such examples, the end criterion of first cyclical deposition process 102 is reached when a desired thickness of the first hardmask layer (e.g., the metal oxide layer) is deposited or alternatively when a predetermined number of deposition cycle of the first cyclical deposition process 102 have been performed. As a non-limiting example, the first cyclical deposition process 102 can be terminated after a desired thickness of an aluminum oxide layer has been deposited on the substrate and particular over a first region and a second region of the substrate.

In accordance with examples of the disclosure, the first hardmask layer (e.g., an aluminum oxide layer) is deposited to an average layer thickness of less 50 Angstroms, less 45 Angstroms, less 40 Angstroms, less 35 Angstroms, less 30 Angstroms, less 25 Angstroms, less 20 Angstroms, less 15 Angstroms, or less 10 Angstroms. In some embodiments the first hardmask layer (e.g., an aluminum oxide layer) is deposited to an average layer thickness between 10 Angstroms and 50 Angstroms.

In accordance with examples of the disclosure, the first hardmask layer (e.g., an aluminum oxide layer) is deposited in an amorphous state. In such examples, the amorphous first hardmask layer can improve subsequent selective epitaxial deposition processes by inhibiting deposition on an amorphous surface of the amorphous first hardmask layer. In such examples, the crystallinity of the first hardmask layer can be determined by employing X-ray diffraction analysis, for example.

In accordance with examples of the disclosure, method 100 includes performing one or more deposition cycles of a second cyclical deposition process 110 to deposited a second hardmask layer comprising a doped metal oxide layer. In such examples the second hardmask layer (i.e., the doped metal oxide layer) is deposited on the first hardmask layer (i.e., the metal oxide layer). In some embodiments, the second hardmask layer is deposited directly on the first hardmask layer thereby forming the bilayer hardmask.

In accordance with examples of the disclosure, the second cyclical deposition process 110 is performed to deposit a second hardmask layer (e.g., a doped metal oxide layer) on the first hardmask layer, and in particular embodiments directly on the first hardmask layer thereby forming the bilayer hardmask.

In accordance with examples of the disclosure, the second cyclical deposition process 110 comprises providing a second metal precursor to the reaction chamber (step 112), providing a second oxidizer to the reaction chamber (step 114), and providing a dopant precursor to the reaction chamber (step 116). In such examples, the second hardmask layer can include a doped aluminum oxide. In some embodiments, the doped aluminum oxide comprises a hafnium doped aluminum oxide (HfAlO). In some embodiments, the doped aluminum oxide comprises a zirconium doped aluminum oxide.

In accordance with examples of the disclosure, the second cyclical deposition process 110 includes providing a second metal precursor to the reaction chamber (step 112). In such examples, the second metal precursor can include aluminum precursor. In such examples, the aluminum precursor is selected from the group consisting of trimethyl aluminum (TMA), dimethylaluminumchloride, aluminum trichloride (AlCl₃), dimethylaluminum isopropoxide (DMAI), tris(tertbutyl)aluminum (TTBA), tris(isopropoxide)aluminum (TIPA), and triethyl aluminum (TEA). In some embodiments, the aluminum precursor comprises dimethylaluminum isopropoxide (DMAI).

In accordance with examples of the disclosure, the second cyclical deposition process 110 includes providing a second oxidizer to the reaction chamber (step 114). In such examples, the second oxidizer is selected from the group consisting of water (H₂O), hydrogen peroxide (H₂O₂), ozone (O₃), oxides of nitrogen, such as, for example, nitrogen monoxide (NO), nitrous oxide (N₂O), and nitrogen dioxide (NO₂). In some embodiments, the second oxidizer comprises an organic alcohol, such as, for example, isopropyl alcohol.

In accordance with examples of the disclosure, the second cyclical deposition process 110 includes providing a dopant precursor to the reaction chamber (step 116). In some embodiments the dopant precursor is a hafnium dopant precursor. In such embodiments, the hafnium dopant precursor is selected from the group consisting of hafnium tetrachloride (HfCl₄), hafnium tetraiodide (Hfl₄), hafnium tetrabromide (HfBr₄), tetrakis(ethylmethylamido)hafnium (Hf(NEtMe)₄), tetrakis(dimethylamido)hafnium (Hf(NMe₂)₄), tetrakis(diethylamido)hafnium (Hf(NEt₂)₄), (tris(dimethylamido)cyclopentadienylhafnium HfCp(NMe₂)₃, and bis(methylcyclopentadienyl)methoxymethyl hafnium (MeCp)₂Hf(CH)₃(OCH₃). In some embodiments, the dopant precursor is a zirconium dopant precursor. In such embodiments, the zirconium dopant precursor is selected from the group consisting of Zr(NEtMe)₄, ZrCp₂(NMe₂)₂, Zr(OtBu)₄.

In accordance with examples of the disclosure, the second cyclical deposition process 110 is repeated one or more time until a desired end criterion is reach (decision block 118). In such examples, the end criterion of second cyclical deposition process 110 is reached when a desired thickness of the second hardmask layer (e.g., the doped metal oxide layer) is deposited or alternatively when a predetermined number of deposition cycle of the second cyclical deposition process 110 have been performed. As a non-limiting example, the second cyclical deposition process 110 can be terminated after a desired thickness of a hafnium doped aluminum oxide layer or a zirconium doped aluminum oxide layer has been deposited on the substrate and particular over the first and second region of the substrate.

In accordance with examples of the disclosure, the second hardmask layer (e.g., a hafnium or zirconium doped aluminum oxide layer) is deposited to an average layer thickness of less 25 Angstroms, less 20 Angstroms, less 15 Angstroms, less 10 Angstroms, or less than 5 Angstroms. In some embodiments the second hardmask layer (e.g., a hafnium or zirconium doped aluminum oxide layer) is deposited to an average layer thickness between 5 Angstroms and 50 Angstroms.

In accordance with examples of the disclosure, the individual steps of the second cyclical deposition process 110 (i.e., step 112, step 114, and step 116) can be performed in any order or sequence, in parallel (or at least partially in parallel), and can include multiple repetitions of one or more of the steps. In such examples, each of step 112, step 114, and step 116, can be repeated prior to proceeding to a subsequent step of second cyclical deposition process 110. In some embodiments, step 112 can be repeated one or more times prior to proceeding to step 114. In some embodiments, step 114 can be repeated one or more times prior to proceeding to step 116. By varying the ratio of the number of performed steps within one or more unit deposition cycles of the second cyclical deposition process 110, the dopant concentration (e.g., hafnium or zirconium) can be manipulated or controlled in the deposited doped metal oxide layer.

In accordance with examples of the disclosure, the doped metal oxide layer deposited by the second cyclical deposition process 110 has a dopant concentration greater than 0 atomic-%, greater than 5 atomic-%, greater than 10 atomic-%, greater than 15 atomic-%, greater than 20 atomic-%, greater than 25 atomic-%, greater than 30 atomic-%, greater than 35 atomic-%, greater than 40 atomic-%, greater than 45 atomic-%, greater than 50 atomic-%, greater than 55 atomic-%, or greater than 60 atomic-%. In some embodiments, the doped metal oxide layer deposited by the second cyclical deposition process 110 has a dopant concentration between 20 atomic-% and 60 atomic-%.

In some embodiments, the doped metal oxide layer deposited by the second cyclical deposition process 110 is a hafnium doped aluminum oxide which has a hafnium dopant concentration greater than 0 atomic-%, greater than 5 atomic-%, greater than 10 atomic-%, greater than 15 atomic-%, greater than 20 atomic-%, greater than 25 atomic-%, greater than 30 atomic-%, greater than 35 atomic-%, greater than 40 atomic-%, greater than 45 atomic-%, greater than 50 atomic-%, greater than 55 atomic-%, or greater than 60 atomic-%. In some embodiments, the hafnium doped aluminum oxide deposited by the second cyclical deposition process 110 has a hafnium dopant concentration between 20 atomic-% and 60 atomic-%.

In some embodiments, the doped metal oxide layer deposited by the second cyclical deposition process 110 is a zirconium doped aluminum oxide which has a zirconium dopant concentration greater than 0 atomic-%, greater than 5 atomic-%, greater than 10 atomic-%, greater than 15 atomic-%, greater than 20 atomic-%, greater than 25 atomic-%, greater than 30 atomic-%, greater than 35 atomic-%, greater than 40 atomic-%, greater than 45 atomic-%, greater than 50 atomic-%, greater than 55 atomic-%, or greater than 60 atomic-%. In some embodiments, the zirconium doped aluminum oxide deposited by the second cyclical deposition process 110 has a zirconium dopant concentration between 20 atomic-% and 60 atomic-%.

In the above embodiments the dopant concentration can be determined employing X-ray fluorescence (XRF) for example.

In accordance with other examples of the disclosure, the first hardmask layer can comprise a doped metal oxide layer. In such examples, the first cyclical deposition process 102 includes an additional step of providing a first dopant precursor to the reaction chamber. In such examples, the first unit deposition cycle of the first cyclical deposition process 102 comprises, providing a first metal precursor to the reaction chamber, providing a first oxidizer to the reaction chamber, and providing a first dopant precursor to the reaction chamber. The additional step of providing the first dopant precursor to the reaction chamber can be same as, or similar to the step 116 of method 100. In such examples, the first cyclical deposition process 102 is employed to deposit a first doped metal oxide layer and the second cyclical deposition process 110 is employed to deposited a second doped metal oxide layer directly on the first doped metal oxide layer. In such examples, the second unit deposition cycle of the second cyclical deposition process 110 comprises, providing a second metal precursor to the reaction chamber, providing a second oxidizer to the reaction chamber, and providing a second dopant precursor to the reaction chamber. In such examples, the first doped metal oxide layer can comprise a first doped aluminum oxide, doped with either hafnium or zirconium as described above.

In accordance with other examples of the disclosure, the first hardmask layer can comprise a doped metal oxide layer and the second hardmask layer can comprises a metal oxide layer. In such examples, the first cyclical deposition process 102 includes an additional step of providing a first dopant precursor to the reaction chamber. In such examples, the first unit deposition cycle of the first cyclical deposition process 102 comprises, providing a first metal precursor to the reaction chamber, providing a first oxidizer to the reaction chamber, and providing a first dopant precursor to the reaction chamber. In such examples, the second unit deposition cycle of the second cyclical deposition process 110 omits the step of providing the dopant precursor to the reaction chamber (step 116) such that the second cyclical deposition process deposits a metal oxide layer, i.e., an undoped metal oxide layer. In such examples, the second hardmask layer can comprises an aluminum oxide layer.

The additional step of providing the first dopant precursor to the reaction chamber can be same as, or similar to the step 116 of method 100. In such examples, the first cyclical deposition process 102 is employed to deposit a first doped metal oxide layer and the second cyclical deposition process 110 is employed to deposited a second doped metal oxide layer directly on the first doped metal oxide layer. In such examples, the second unit deposition cycle of the second cyclical deposition process 110 comprises, providing a second metal precursor to the reaction chamber, providing a second oxidizer to the reaction chamber, and providing a second dopant precursor to the reaction chamber. In such examples, the first doped metal oxide layer can comprise a first doped aluminum oxide, doped with either hafnium or zirconium as described above.

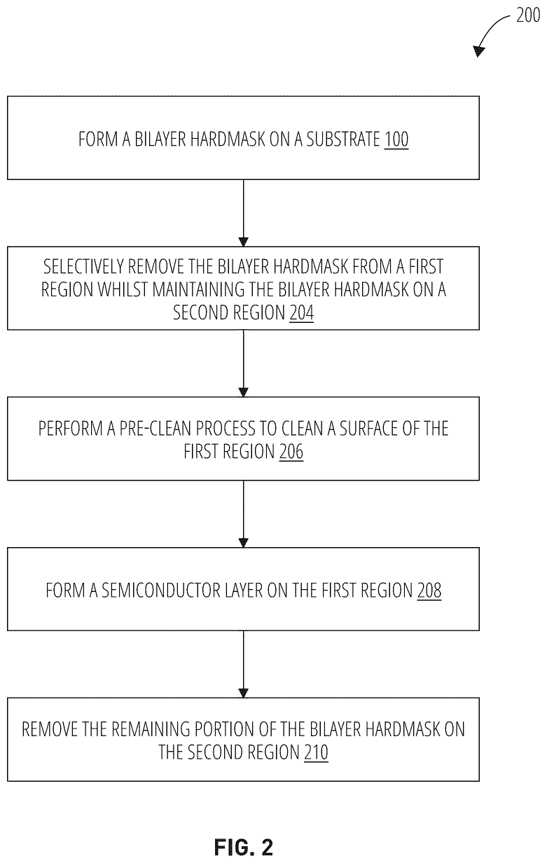

Various embodiments of the present disclosure also relate to methods for semiconductor structures including a bilayer hardmask as well as semiconductor structures formed by employing such a bilayer hardmask. In some embodiments, the bilayer hardmasks of the present disclosure may be employed in the fabrication of a CMOS device structure. In accordance with examples of the disclosure, method 200 (FIG. 2) illustrates the employment of a bilayer hardmask of the present disclosure in the fabrication of CMOS device structures.

In accordance with examples of the disclosure, method 200 includes seating a substrate including a first region and a second region in a reaction chamber and forming a bilayer hardmask on the substrate (method 100), as previously described above with reference to FIG. 1.

In accordance with examples of the disclosure, method 200 includes selectively removing the bilayer hardmask from over the first region of the substrate to expose a surface of the first region of the substrate (step 204). In such examples, selectively removing the bilayer hardmask from the first region of the substrate further comprises forming a patterned resist layer over the second region of the substrate and contacting an exposed region of the bilayer hardmask with a wet etchant. In such examples, the wet etchant is selected from the group consisting of, hydrofluoric acid, sulfuric acid, and phosphoric acid, as well as diluted and hydrogen peroxide mixtures of the preceding wet etchants.

In accordance with examples of the disclosure, method 200 includes performing a cleaning process on the exposed surface of the first region of substrate thereby forming a cleaned first region surface (step 206). In such examples, the cleaning process comprises, contacting the exposed surface of the first region of the substrate with a plasma generated from a gas mixture comprising a fluorine containing gas (e.g., hydrofluoric acid, NF₃, NF₃*) and ammonia. In such examples, the cleaning process removes at least a portion of the second hardmask layer from over the second region of the substrate. In such examples, the cleaning process removes the second hardmask layer from over the second region of the substrate. In other examples, the cleaning process comprises a vapor phase etching process. In such examples, the vapor phase etching process includes heating the substrate (e.g., to a temperature between 20° C. and 100° C.) and contacting the substrate with a vapor phase etchant (e.g., hydrofluoric acid vapor).

In accordance with examples of the disclosure, method 200 includes forming a semiconductor layer on the cleaned first region surface (step 208). In such examples forming the semiconductor layer comprises depositing a semiconductor layer directly on the cleaned first region surface by an epitaxial deposition process. In such examples, the epitaxial deposition process is a selective epitaxial deposition process. In some embodiments, the epitaxial deposition process can be employed to deposit a SiGe layer, or a SiP layer on the cleaned first surface.

In accordance with examples of the disclosure, method 200 includes removing any remaining portions of the bilayer hardmask from over the second region of the substrate (step 210).

In accordance with examples of the disclosure, the bilayer hardmasks of the present disclosure can be employed in other methods of fabricating CMOS device structures. In such examples, the processes include seating a substrate comprising a NMOS region and a PMOS region into a reaction chamber and depositing a bilayer hardmask over the NMOS region and over the PMOS region. In such examples depositing the bilayer hardmask comprises, depositing a metal oxide layer over both the NMOS region and the PMOS region, and depositing a doped metal oxide layer over the first hardmask layer. In some embodiments, the bilayer hardmask is deposited by a cyclical deposition process, such as an atomic layer deposition process, for example. In such examples, the processes can further include selectively removing the bilayer hardmask over the NMOS region to expose a surface of the NMOS region and performing a cleaning process on the exposed surface of the NMOS region thereby forming a clean NMOS surface. In such examples, selectively removing the bilayer hardmask over the NMOS region can further include forming a patterned resist layer over the PMOS region and contacting an exposed region of the bilayer hardmask with a wet etchant selected from the group consisting of hydrofluoric acid, sulfuric acid, and phosphoric acid. In such examples, the processes can further include depositing a semiconductor layer on the clean NMOS surface. In such examples, the semiconductor layer is deposited by an epitaxial deposition process.

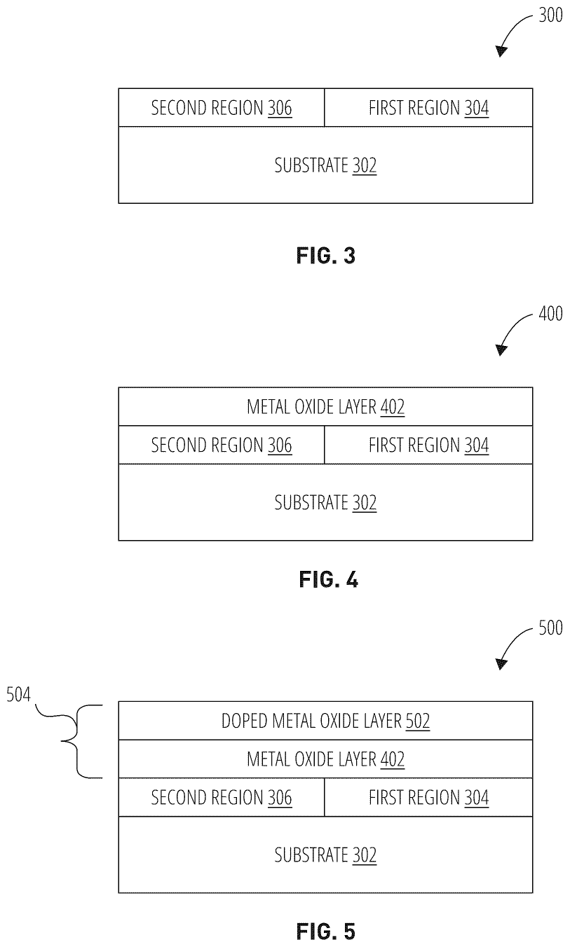

The various embodiments of the present disclosure also include semiconductor structures formed by the methods disclosure herein. In accordance with examples of the disclosure, FIG. 3 illustrates a semiconductor structure 300 including a substrate 302 comprises a first region 304 (e.g., a NMOS region) and a second region 306 (e.g., a PMOS region).

In accordance with examples of the disclosure, FIG. 4 illustrates a semiconductor structure 400 including a first hardmask layer comprising a metal oxide layers 402 (e.g., an aluminum oxide layer) deposited directly on the first region 304 and second region 306 of the substrate 302. In such examples the metal oxide layer 402 is deposited by the first cyclical deposition process 102 of method 100 (FIG. 1).

In accordance with examples of the disclosure, FIG. 5 illustrates a semiconductor structure 500 including a second hardmask layer comprising a doped metal oxide layer 502 (e.g., a hafnium or zirconium doped aluminum oxide layer) deposited directly on the metal oxide layer 402. As illustrated in FIG. 5 the metal oxide layer 402 and the doped metal oxide layer 502 together form the bilayer hardmask 504. In such examples, the doped metal oxide layer 502 is deposited by the second cyclical deposition process 110 of method 100 (FIG. 1).

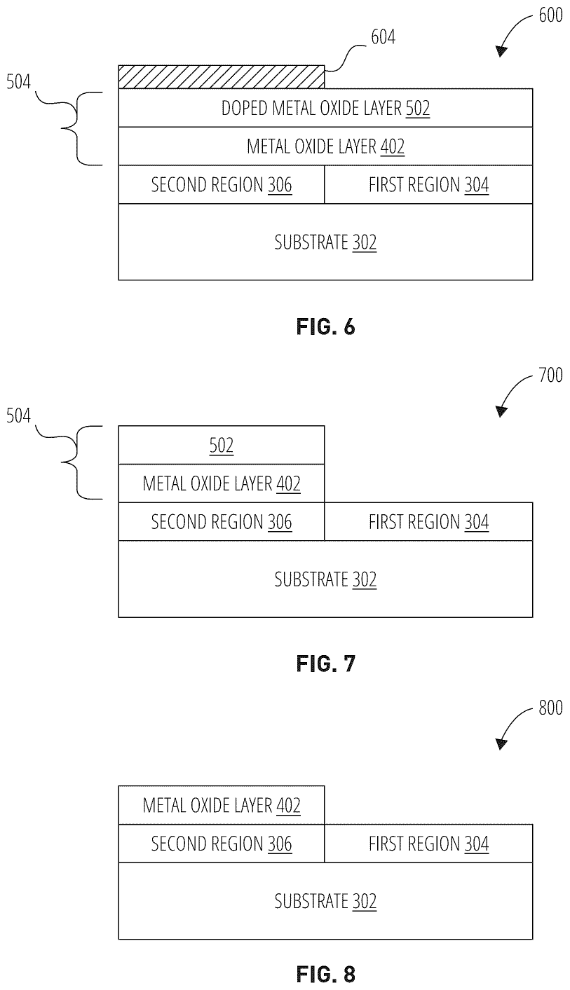

In accordance with examples of the disclosure, FIG. 6 illustrates a semiconductor structure 600 including a patterned resist layer 602 formed over the second region 306 of the substrate 302 (e.g., the PMOS region).

In accordance with examples of the disclosure, FIG. 7 illustrates a semiconductor structure 700 after selectively removing the bilayer hardmask 504 from over the first region 304 of the substrate 302 while maintaining the bilayer hardmask 504 over the second region 306 of the substrate 302, as described above with reference to step 204 of method 200 (FIG. 2). In such examples any remaining portions of the patterned resist layer can be removed after the etch process.

In accordance with examples of the disclosure, FIG. 8 illustrates a semiconductor structure 800 after performing a pre-clean process to clean a surface of the first region 304 of the substrate 302, as described above with reference to step 206 of method 200 (FIG. 2). In such examples, the cleaned first region surface can include a clean NMOS surface region. In such examples, the pre-clean process removes the second hardmask layer, i.e., the doped metal oxide layer 502 disposed over the second region 306 of the substrate 302. In such examples, the pre-clean process can remove a portion of the first hardmask layer, i.e., a portion of the metal oxide layer 402.

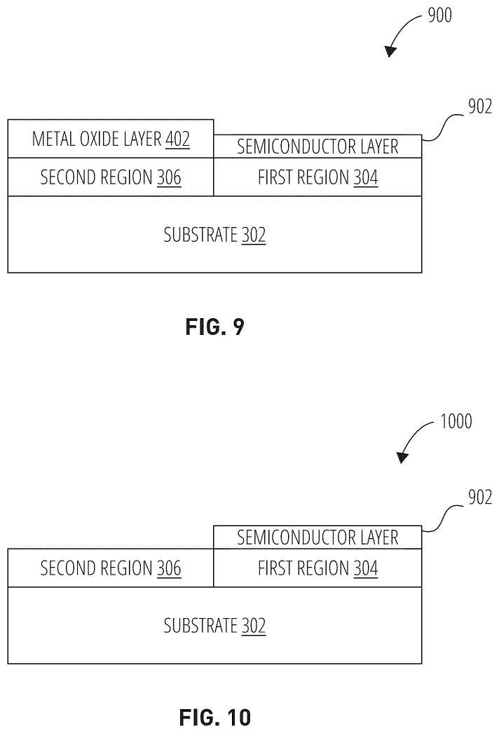

In accordance with examples of the disclosure, FIG. 9 illustrates a semiconductor structure 900 after depositing a semiconductor layer 902 on the first region 304 of the substrate 302. In such examples, the semiconductor layer 902 is deposited by an epitaxial deposition process on the first region 304 (e.g., on an NMOS region). In some embodiments of the disclosure, the epitaxial deposition process is a selective epitaxial deposition process. In such embodiments, the semiconductor layer 902 is deposited selectively over the first region 304 relative to the top surface of the metal oxide layer 402. In such examples, the selective epitaxial deposition process selectively deposits the semiconductor layer 902 preferentially on a clean NMOS surface relative to a surface of the metal oxide layer (e.g., an amorphous surface of the metal oxide layer).

As used herein, the selectivity of the deposition process on surface A relative to surface B can be given as a percentage calculated by [(deposition on surface A)−(deposition on surface B)]/(deposition on the surface A). Deposition can be measured in any of a variety of ways. For example, deposition may be given as the measured thickness of the deposited material, or may be given as the measured amount of material deposited.

In accordance with examples of the disclosure, the selectivity of the selective epitaxial deposition process employed for depositing the semiconductor layer 902 on first region 304 relative to top surface of the metal oxide layer 402 is greater than 10%, greater than 50%, greater than 75%, greater than 85%, greater than 90%, greater than 93%, greater than 95%, greater than 98%, greater than 99%, greater than 99.5%, equal to about 100%.

In accordance with examples of the disclosure, FIG. 10 illustrates a semiconductor structure 1000 after removing a remaining portion of the bilayer hardmask disposed over the second region 306 (e.g., over a PMOS region). In such examples, the remaining portion of the bilayer hardmask comprises a remaining portion of the doped metal oxide layer 502. In such examples, the remaining portion of the doped metal oxide layer 502 can be removed by various etch methods.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method of forming a bilayer hardmask on a substrate in a reaction chamber, the method comprising:
performing one or more deposition cycles of a first cyclical deposition process to deposit a first hardmask layer comprising a metal oxide layer on the substrate; and
performing one or more deposition cycles of a second cyclical deposition process to deposit a second hardmask layer comprising a doped metal oxide layer directly on the metal oxide layer.

2. The method of claim 1, wherein a first unit deposition cycle of the first cyclical deposition process comprises providing a first metal precursor to the reaction chamber and providing a first oxidizer to the reaction chamber.

3. The method of claim 2, wherein the first hardmask layer comprises an aluminum oxide.

4. The method of claim 2, wherein the first unit deposition cycle further comprises providing a first dopant precursor to the reaction chamber.

5. The method of claim 4, wherein the first hardmask layer comprises a first doped aluminum oxide.

6. The method of claim 2, wherein a second unit deposition cycle of the second cyclical deposition process comprises providing a second metal precursor to the reaction chamber, providing a second oxidizer to the reaction chamber, and providing a second dopant precursor to the reaction chamber.

7. The method of claim 6, wherein the second hardmask layer comprises a second doped aluminum oxide.

8. The method of claim 7, wherein the second hardmask layer comprises a hafnium doped aluminum oxide (HfAlO).

9. The method of claim 8, wherein the hafnium doped aluminum oxide has a hafnium concentration between 20 atomic-% and 60 atomic-%.

10. The method of claim 7, wherein the second hardmask layer comprises a zirconium doped aluminum oxide (ZrAlO).

11. The method of claim 10, wherein the zirconium doped aluminum oxide has a zirconium concentration between 20 atomic-% and 60 atomic-%.

12. The method of claim 1, wherein the bilayer hardmask has an average layer thickness of less than 50 Angstroms.

13. A method of forming a semiconductor structure, the method comprising:
seating a substrate comprising a NMOS region and a PMOS region into a reaction chamber;
depositing a bilayer hardmask over the NMOS region and over the PMOS region, wherein depositing the bilayer hardmask comprises;
depositing a metal oxide layer over both the NMOS region and the PMOS region;
depositing a doped metal oxide layer directly on the metal oxide layer;
selectively removing the bilayer hardmask over the NMOS region to expose a surface of the NMOS region;
performing a cleaning process on the exposed surface of the NMOS region thereby forming a clean NMOS surface;
depositing a semiconductor layer on the clean NMOS surface; and
removing a remaining portion of the bilayer hardmask disposed over the PMOS region.

14. The method of claim 13, wherein selectively removing the bilayer hardmask over the NMOS region further comprises, forming a patterned resist layer over the PMOS region and contacting an exposed region of the bilayer hardmask with a wet etchant selected from the group consisting of hydrofluoric acid, sulfuric acid, and phosphoric acid.

15. The method of claim 13, wherein the cleaning process removes the doped metal oxide layer over the PMOS region while maintaining at least the metal oxide layer over the PMOS region.

16. The method of claim 15, wherein depositing the semiconductor layer comprises a selective epitaxial deposition process.

17. The method of claim 16, wherein the selective epitaxial deposition process selectively deposits the semiconductor layer preferentially on the clean NMOS surface relative to a surface of the metal oxide layer.

18. The method of claim 17, wherein the surface of the metal oxide layer comprises an amorphous surface.

19. The method of claim 13, wherein the metal oxide layer comprise an aluminum oxide layer and the doped metal oxide layer comprises a doped aluminum oxide layer.

20. The method of claim 19, wherein a dopant concentration in the doped aluminum oxide layer is between 20 atomic-% and 60 atomic-%.
